(19) United States
(12) Patent Application Publication
(10) Pub. No.: US 2008/0150028 A1
(43) Pub. Date: Jun. 26, 2008

(54) ZERO INTERFACE POLYSILICON TO POLYSILICON GATE FOR SEMICONDUCTOR DEVICE

(75) Inventors: Robert Bertram Ogle, San Jose, CA (US); Joong Jeon, Los Altos, CA (US); Jon Kluth, Hopewell Junction, NY (US)

Correspondence Address: AMIN, TUROCY & CALVIN, LLP, 24TH FLOOR, NATIONAL CITY CENTER, 1900 EAST NINTH STREET, CLEVELAND, OH, 44114, US

(73) Assignee: ADVANCED MICRO DEVICES, INC., Austin, TX (US)

(21) Appl. No.: 11/614,774

(22) Filed: Dec. 21, 2006

(51) Int. Cl. H01L 29/78; C23C 16/00; H01L 21/4763

(52) U.S. Cl. 257/365; 118/715; 438/592; 257/E21.495; 257/E29.345

(57) ABSTRACT

A system and method are disclosed for processing a zero angstrom oxide interface dual poly gate structure for a semiconductor device. An exemplary method can include removing an oxide from a surface of a first poly layer and forming a second poly layer on the first poly layer in a processing chamber. A transfer of the structure is not needed from an oxide removal tool to, for example, a poly layer formation tool, an implant tool, and the like. As a result, impurities containing a silicon oxide caused by exposure of the first poly layer to an oxygen-containing atmosphere do not form at the interface of the first and second poly layers.

### TECHNICAL FIELD

The subject invention generally relates to zero angstrom oxide interface poly to poly gate for use in connection with semiconductor devices such as logic devices.

### BACKGROUND

Logic devices are currently in widespread use in electronic components. Logic device may include transistor-transistor logic (TTL), diode-transistor logic (DTL), emitter coupled logic (ECL), complementary metal oxide semiconductor (CMOS), and the like.

CMOS devices have become widely used in the semiconductor industry. CMOS typically includes many p-type MOS transistors and n-type MOS transistors, which are formed in the corresponding wells in a substrate. The source and drain regions are typically formed by adding dopants to targeted regions on either side of a channel. A gate dielectric or gate oxide is formed over the channel, and a gate electrode or gate contact is formed over the gate dielectric. The gate dielectric and gate electrode layers are then patterned to form a gate structure overlying the channel region of the substrate.

In the semiconductor industry, there is a continuing trend toward higher device densities. To achieve these high densities there have been, and continue to be, efforts toward scaling down device dimensions (e.g., at sub-micron levels) on semiconductor wafers. In order to accomplish such high device packing densities, smaller feature sizes and more precise feature shapes are required. This may include the width, thickness and spacing of interconnecting lines, spacing and diameter of contact holes, and the surface geometry, such as corners and edges, of various features.

The requirement of small features with close spacing between adjacent features requires sophisticated manufacturing techniques to ensure that quality and operability of the features are not compromised for the purpose of reducing feature size. Among the many aspects related to improving logic device fabrication processing to achieve higher density devices, the ability to form thin layers, which are substantially free from impurities and defects, remains critical to the structural integrity of smaller features as well as to the performance of the device with respect to increasing the speed of the device. Even minor impurities or defects present in thin layers tend to result in poor device characteristics, thereby reducing the effectiveness of the logic device.

### SUMMARY

The following is a summary of the invention in order to provide a basic understanding of some aspects of the invention. This summary is not intended to identify key/critical elements of the invention or to delineate the scope of the invention. Its sole purpose is to present some concepts of the invention in a simplified form as a prelude to the more detailed description that is presented later.

The subject invention provides a method and system that facilitates processing a zero angstrom oxide interface dual poly gate structure for a semiconductor device. The method can include removing an oxide and/or oxide layer on the surface of a first poly layer and forming a second poly layer on the first poly layer in the same processing chamber. A transfer of the structure is not needed from an oxide removal tool to, for example, a poly layer formation tool, an implant tool, and the like. As a result, the substrate is not exposed to an oxygen-containing atmosphere after removal of the oxide layer from the first poly layer and before formation of the second poly layer. Consequently, impurities containing a silicon oxide caused by exposure of the first poly layer to an oxygen-containing atmosphere do not form at the interface of the first and second poly layers, thus improving productivity, quality, and reliability of the resultant semiconductor devices.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates a cross sectional view of a portion of a semiconductor device containing a zero angstrom oxide interface dual poly gate structure in accordance with one aspect of the invention.

FIG. 2 shows a cross sectional view of forming a zero angstrom oxide interface dual poly gate structure for a semiconductor device in accordance with one aspect of the invention.

FIG. 3 shows a cross sectional view of forming a zero angstrom oxide interface dual poly gate structure for a semiconductor device in accordance with one aspect of the invention.

FIG. 4 shows a cross sectional view of forming a zero angstrom oxide interface dual poly gate structure for a semiconductor device in accordance with one aspect of the invention.

FIG. 5 shows a cross sectional view of forming a zero angstrom oxide interface dual poly gate structure for a semiconductor device in accordance with one aspect of the invention.

FIG. 6 shows a cross sectional view of forming a zero angstrom oxide interface dual poly gate structure for a semiconductor device in accordance with one aspect of the invention.

FIG. 7 shows a cross sectional view of a semiconductor device containing a zero angstrom oxide interface dual poly gate structure in accordance with one aspect of the invention.

FIG. 8 shows a schematic block diagram of a system for processing a zero angstrom oxide interface dual poly gate structure for a semiconductor device in accordance with one or more aspects of the subject invention.

FIG. 9 shows a schematic block diagram illustrating a processing chamber of a system for processing a zero angstrom oxide interface dual poly gate structure for a semiconductor device associated with a poly layer formation component and an oxide removing component in accordance with one or more aspects of the subject invention.

FIG. 10 shows a schematic block diagram illustrating a processing chamber of a system for processing a zero angstrom oxide interface dual poly gate structure for a semiconductor device associated with a poly layer formation component, an oxide removing component, an insulator layer formation component, and a high-k layer formation component, and a metal gate layer formation component in accordance with one or more aspects of the subject invention.

### DETAILED DESCRIPTION

The invention is now described with reference to the drawings, wherein like reference numerals are used to refer to like elements throughout. In the following description, for purposes of explanation, numerous specific details are set forth in order to provide a thorough understanding of the subject invention. It may be evident, however, that the invention can be practiced without these specific details. In other instances, well-known structures and devices are shown in block diagram form in order to facilitate describing the invention.

Exposure of poly layers to an oxygen-containing atmosphere during the manufacturing process of a semiconductor device may cause impurities in the gate structure of a semiconductor device. For example, an oxide and/or oxide layer may undesirably form along an upper surface of a poly layer of the semiconductor device when the structure contacts an oxygen-containing atmosphere during the manufacturing process. Such impurities can have a negative impact upon the quality of the resultant semiconductor device by altering the desired electrical properties of and interactions between components on the resultant semiconductor device. Thus, an efficient system and/or method to form dual poly structures are desirable to increase productivity, quality, and reliability in semiconductor device manufacture.

Fabrication of a semiconductor device such as a logic device generally involves multiple acts of layer formation. A zero angstrom oxide interface dual poly gate structure for a semiconductor device includes first and second poly layers that are vertically adjacent one another. An oxide and/or oxide layer formed on the first poly layer is removed in a processing chamber by contacting the first poly layer with at least one of hydrogen, nitrogen, fluorine-containing compound, and other oxide removing ambients and then the second poly layer is formed on the first poly layer in the same processing chamber. No transfer of the substrate between processing tools is necessary. As a result, the interface of the two poly layers contains substantially no oxide. That is, a zero angstrom oxide interface is formed. Impurities (e.g., silicon oxide) at the interface have a negative impact on the quality of the resultant semiconductor device by altering the desired electrical properties of and interactions between components on the semiconductor device. Since the interface of the two poly layers contains substantially no oxide, the negative impact does not occur in accordance with the subject invention.

The subject invention relates to a method and system for processing a zero angstrom oxide interface dual poly gate structure for a semiconductor device. The subject invention also relates to a dual poly gate structure for a semiconductor device with a zero angstrom oxide interface. That is, the interface between two poly layers in the dual poly gate structure contains substantially no oxide compound.

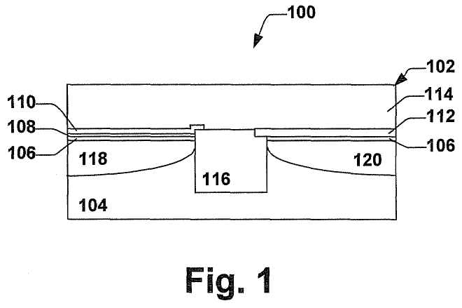

FIG. 1 shows a cross sectional view of a portion of a semiconductor device 100 containing a zero angstrom oxide interface dual poly gate structure 102 in accordance with one aspect of the invention. The semiconductor device 100 contains one or more zero angstrom oxide interface dual poly gate structures 102. The semiconductor device 100 may generally contain a substrate 104, and an insulator layer 106, a high-k layer 108, a metal gate 110, a first poly layer 112, and a second poly layer 114. The substrate 104 generally contains shallow trench isolation (STI) 116. The substrate 104 also generally contains a N⁺ region and a P⁺ region adjacent to the STI region 116. In one embodiment, the substrate 104 may contain a N⁺ region 118 and a P⁺ region 120. In another embodiment, the substrate 104 may contain a P⁺ region 118 and a N⁺ region 120.

The zero angstrom oxide interface dual poly gate structure 102 may contain a plurality of features containing, for example, an insulator layer 106, a first poly layer 1 112, and a second poly layer 114. Other features are not shown for brevity. The poly layers 112, 114 contain polysilicon. The first poly layer 112 can be referred to as a “poly 1,” while the second poly layer 114 can be referred to as a “poly 2.”

The substrate 104 may be substantially any suitable semiconductor substrate 104 such as a silicon substrate 104. The insulator layer 106 may be substantially any insulator material suitable for a semiconductor device 100, for example, silicon oxynitride (SiON), silicon nitride (SiN), silicon oxide (SiO₂), and the like. The high-k layer 108 may be substantially any high-k material suitable for a semiconductor device 100. The metal gate 110 may be substantially any metal material suitable for a semiconductor device 100. The STI 116 may be filled with an oxide material.

The poly 1 112 contains polysilicon. If the poly 1 112 contacts an oxygen-containing environment during the manufacturing process, an oxide and/or oxide layer may form along the upper poly 1 surface. The oxide and/or oxide layer may contain silicon oxide. Often times, the thickness of the oxide layer is a function of the time that the poly 1 112 is exposed to the oxygen-containing environment as well as the amount of oxygen in the oxygen-containing environment. After the poly 1 formation and before a poly 2 is formed on the poly 1 layer, any oxide that may be present on the surface of the poly 1 112 is removed. The oxide is removed by contacting the poly 1 112 with at least one of hydrogen, nitrogen, fluorine-containing compound, and other oxide removing ambients in a processing chamber under suitable conditions. As a result, an interface between the two poly layers 112, 114 contains substantially no oxide and/or oxide layer.

Containing substantially no oxide and/or oxide layer at the interface between the two poly layers means that the interface does not contain or is not bound to oxygen that is detectable above the background noise level by a secondary ion mass spectrometer (SIMS). The thickness of the oxide and/or oxide layer at the interface of the two poly layers is below the minimum detectable thickness of oxide using a SIMS, which is the background noise level, meaning that virtually no oxide is at the interface. The interface of the two poly layers contains an oxide layer of thickness of about zero Å (angstrom), or the interface of the two poly layers is substantially free of an oxide. It is to be appreciated that substantially any suitable SIMS that is normally used for determining the thickness of an oxide can be used for the subject invention. In one embodiment, the thickness of the oxide compound at the interface of the two poly layers can be determined using a SIMS under the trade designation PH1-6600 available from PerkinElmer, Inc.

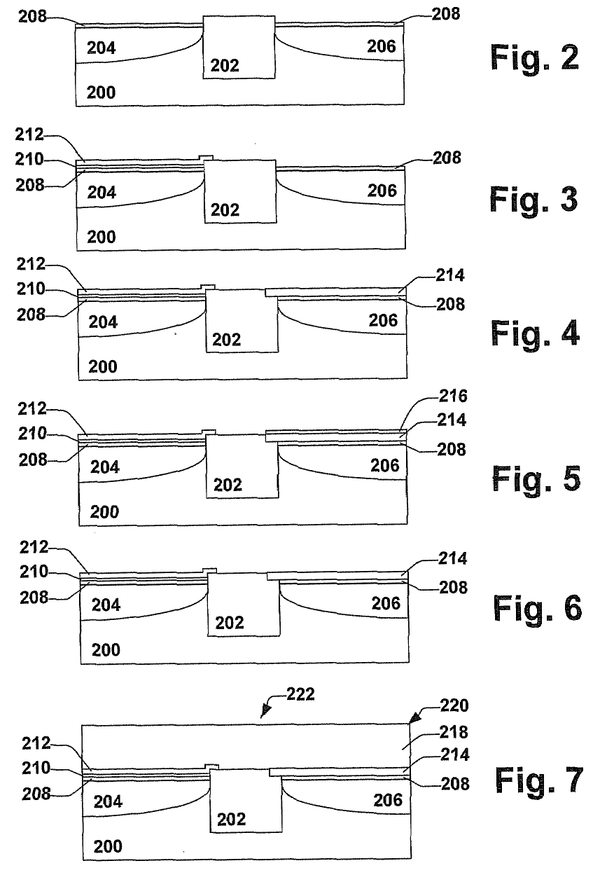

FIGS. 2 to 7 illustrate one of many possible exemplary embodiments of processing a zero angstrom oxide interface dual poly gate structure for a semiconductor device. FIG. 2 illustrates a substrate 200 of a semiconductor device in a processing chamber (not shown). The substrate 200 may be substantially any suitable semiconductor substrate such as a silicon substrate.

The substrate 200 may contain a STI 202. The STI 202 may be formed in the substrate by, for example, etching using a suitable mask to create a desired trench pattern. The STI 202 may be filled with an oxide material such as high density plasma (HDP) oxide or plasma tetraethyl orthosilicate (TEOS).

The substrate 200 also generally contains a N⁺ region and a P⁺ region adjacent to the STI region 202. In one embodiment, the substrate 200 may contain a N⁺ region 204 and a P⁺ region 206. In another embodiment, the substrate 200 may contain a P⁺ region 204 and a N⁺ region 206. Implants of N⁺ and P⁺ may be performed to create the N⁺ region and P⁺ region.

The substrate 200 may contain an insulator layer 208. The insulator layer 208 may be formed on one or more portions of the substrate 200. In one embodiment, the insulator layer 208 is formed over the substantially entire portion of the substrate 200, and then any portion of the insulator layer 208, for example, a STI region 202 is etched away. In another embodiment, the insulator layer 208 is formed over the substrate 200 with a patterned mask, thus directly positioning the portion of the insulator layer 208 on the substrate 200. Examples of the insulator layer 208 may include SiON, SiN, SiO₂, and the like. It is to be appreciated that such an insulator layer can be formed employing suitable techniques including chemical vapor deposition (CVD) and/or thermal oxidation, with an optional patterned mask, followed by an optional etching away and/or etching back one or more portions.

FIG. 3 illustrates formation of a high-k layer 210 and metal gate layer 212. The high-k layer 210 and metal gate layer 212 may be formed on one or more portions of the substrate 200 in the processing chamber. In one embodiment, the high-k layer 210 and metal gate layer 212 are formed over the substantially entire portion of the substrate 200, and then any portion of the insulator layer 208, for example, the P⁺ region 206 is etched away. In another embodiment, high-k layer 210 and metal gate layer 212 are formed over the substrate 200 with a patterned mask, thus directly positioning the portion of the high-k layer 210 and metal gate layer 212 on the substrate 200.

The high-k layer 210 may be substantially any high-k material suitable for a semiconductor device, for example, a metal oxide, such as aluminum oxide (Al₂O₃), tantalum oxide (Ta₂O₅), titanium oxide (TiO₂), zirconium oxide (ZrO₂), hafnium oxide (HfO₂), yttrium oxide (Y₂O₃), silicon zirconium oxide (SiZrO₄), lanthanum oxide (La₂O₅), other corresponding silicates, and the like. It is to be appreciated that such a high-k layer 210 can be formed employing suitable techniques including CVD, physical vapor deposition (PVD), with an optional patterned mask, followed by an optional etching away and/or etching back one or more portions.

The metal gate 212 may be substantially any metal material suitable for a semiconductor device, for example, tungsten (W), aluminum (Al), copper (Cu), titanium nitride (TiN) and gold (Au), and the like. It is to be appreciated that such a metal gate layer 212 can be formed employing suitable techniques including CVD and PVD, with an optional patterned mask, followed by an optional etching away and/or etching back one or more portions.

FIG. 4 illustrates formation of poly 1 214 on one or more portions of the insulator layer 208. The poly 1 214 may optionally be formed in the processing chamber. The poly 1 214 contains polysilicon. In one embodiment, the poly 1 214 may be formed over the substantially entire portion of the substrate 200, and then any portions of the poly 1 214, for example, the N⁺ region 204 may be etched away. In another embodiment, the poly 1 214 may be formed over the substrate 200 with a patterned mask, thus directly positioning the portion of the poly 1 214 on the substrate 200. It is to be appreciated that the poly 1 214 can be formed employing substantially any suitable poly formation techniques including CVD, with an optional patterned mask, followed by an optional etching away and/or etching back one or more portions.

The poly 1 214 has a suitable thickness that depends upon the desired implementations and/or the semiconductor device being fabricated. In one embodiment, the thickness of poly 1 214 is about 0.001 micron or more and about 0.1 micron or less. In another embodiment, the thickness of poly 1 214 is about 0.005 microns or more and about 0.05 microns or less. In yet another embodiment, the thickness of poly 1 214 is about 0.01 micron or more and about 0.03 microns or less.

Although not shown, after the poly 1 214 formation, all or portions of the substrate 200 may be subject to substantially any semiconductor device fabrication processes. General examples of the semiconductor device fabrication processes include masking, patterning, etching, planarization, thermal oxidation, implant, annealing, thermal treatment, and deposition techniques normally used for making semiconductor devices.

For example, in one embodiment, the poly 1 214 may optionally be etched back by substantially any suitable method, such as by reactive ion etch (RIE). In another embodiment, although not shown, one or more portions of the poly 1 214 may optionally be implanted with oxygen to form a silicon oxide layer in one or more portions of the poly 1 214. Prior to the implantation, a mask such as a patterned photoresist may cover one or more portions of the surface of the poly 1 214. In one embodiment, implantation of oxygen into the poly 1 214 is performed with the patterned mask, thus directly positioning the region of the implantation of oxygen into the poly 1 214. The presence of a patterned mask layer, coupled with selectively chosen implant energy, dose and angle, results in relatively defined area of formation of silicon oxide layer.

Although not shown, the processing chamber is defined by a housing having a plurality of walls. It is to be appreciated that substantially any suitable type of process chamber can be used for the subject invention. In one embodiment, the processing chamber may be a small volume processing chamber. In another embodiment, the processing chamber may be a big batch processing chamber. In yet another embodiment, the processing chamber may be an epitaxial growth chamber, a CVD chamber, a PVD chamber, or other commonly available semiconductor processing chamber, with or without appropriate modifications. The processing chamber suitable to the subject invention can be substantially any enclosure associated with one or more gas and/or liquid inlets to deliver gaseous and/or liquid chemicals for forming the poly layers and for removing oxide, and at least one gas and/or liquid outlet for evacuating the enclosure. The processing chamber may have sub-chambers.

In one embodiment, the processing chamber is a small volume processing chamber, not a large batch chamber that can process 100 wafer substrates. In one embodiment, the small volume processing chamber can process about 10 or fewer wafer substrates. In another embodiment, the small volume processing chamber can process about 5 or fewer wafer substrates. In yet another embodiment, the small volume processing chamber can process about 2 or fewer wafer substrates.

If the processing chamber contains any oxygen-containing species such as air, an oxide and/or oxide layer 216 tends to grow along the upper poly 1 surface, as illustrated in FIG. 5. Often times, the thickness of the oxide layer 216 is a function of the time that the poly 1 214 is exposed to the oxygen-containing species as well as the amount of oxygen in the oxygen-containing species. After the poly 1 214 formation and before a poly 2 is formed on the poly 1 214, the oxide layer 216 on the surface of the poly 1 214 is removed.

The oxide layer 216 is removed by contacting the oxide layer 216 with at least one of hydrogen, nitrogen, and fluorine-containing compound in the processing chamber under suitable conditions to remove oxide. Examples of the fluorine-containing compound may include F₂, HF, NF₃, SF₆, SF₄, S₂F₂, S₂F₁₀, S₃H₈, CF₃, CF₄, CH₂F₂, CHF₃, CH₃F, C₂H₂F₂, C₂H₄F₆, C₂F₆, C₃F₈, C₄F₈, C₂HF5, C₄F₁₀, CF₂Cl₂, CFCl₃, C₂F₄Cl₂, SiF₄, Si₂F₆, SiHF₃, SiH₂F₂, SiH₃F, SiCl₂F₂, and SiClF₃. In one embodiment, the oxide layer 216 is removed by contacting the oxide layer 216 with hydrogen and/or nitrogen with optional one or more inert gases such as helium, neon, argon, crypton, xenon, and the like. In another embodiment, the oxide layer 216 is removed by contacting the oxide layer 216 with a fluorine-containing compound, optional hydrogen and/or nitrogen, and optional one or more inert gases. In yet another embodiment, the oxide layer 216 is removed by contacting the oxide layer 216 with the fluorine-containing compound and optional one or more inert gases.

The oxide layer 216 is contacted with hydrogen and/or nitrogen, and an optional fluorine-containing compound in the processing chamber at a suitable temperature to facilitate removing the oxide that depends upon, for example, the thickness of the oxide layer 216, the desired implementations and/or the semiconductor device being fabricated. In one embodiment, the oxide layer 216 is contacted with hydrogen and/or nitrogen, and an optional fluorine-containing compound at a temperature of about 200 degrees Celsius or more and about 950 degrees Celsius or less. In another embodiment, the oxide layer 216 is contacted with hydrogen and/or nitrogen, and an optional fluorine-containing compound at a temperature of about 400 degrees Celsius or more and about 900 degrees Celsius or less. In yet another embodiment, the oxide layer 216 is contacted with hydrogen and/or nitrogen, and an optional fluorine-containing compound at a temperature of about 500 degrees Celsius or more and about 850 degrees Celsius or less.

The oxide layer 216 is contacted with hydrogen and/or nitrogen, and an optional fluorine-containing compound in the processing chamber at a suitable pressure to facilitate removing the oxide that depends upon, for example, the thickness of the oxide layer 216, the desired implementations and/or the semiconductor device being fabricated. In one embodiment, the oxide layer 216 is contacted with hydrogen and/or nitrogen, and an optional fluorine-containing compound at a pressure of about 10 Torr or less. In another embodiment, the oxide layer 216 is contacted with hydrogen and/or nitrogen, and an optional fluorine-containing compound at a pressure of about 8 Torr or less. In yet another embodiment, the oxide layer 216 is contacted with hydrogen and/or nitrogen, and an optional fluorine-containing compound at a pressure of about 6 Torr or less.

The oxide layer 216 is contacted with hydrogen and/or nitrogen, and an optional fluorine-containing compound in the processing chamber for a suitable time to facilitate removing the oxide that depends upon, for example, the thickness of the oxide layer 216, the desired implementations and/or the semiconductor device being fabricated. In one embodiment, the oxide layer 216 is contacted with hydrogen and/or nitrogen, and an optional fluorine-containing compound for about 1 second or more and about 30 minutes or less. In another embodiment, the oxide layer 216 is contacted with hydrogen and/or nitrogen, and an optional fluorine-containing compound for about 5 seconds or more and about 10 minutes or less. In yet another embodiment, the oxide layer 216 is contacted with hydrogen and/or nitrogen, and an optional fluorine-containing compound for about 10 seconds or more and about 5 minutes or less.

The processing chamber may contain a sufficient amount of hydrogen and/or nitrogen to facilitate removal of the oxide from the poly 1 214. In one embodiment, the processing chamber contains at least about 20% of hydrogen and/or nitrogen by volume. In another embodiment, the processing chamber contains at least about 40% of hydrogen and/or nitrogen by volume. In yet another embodiment, the processing chamber contains at least about 50% of hydrogen and/or nitrogen by volume. The remaining gas(es) may be one or more inert gases such as helium, neon, argon, krypton, xenon, and the like.

The processing chamber may contain a sufficient amount of fluorine-containing compound to facilitate removal of the oxide from the poly 1 214. In one embodiment, the processing chamber contains at least about 5% of fluorine-containing compound by volume. In another embodiment, the processing chamber contains at least about 10% of fluorine-containing compound by volume. In yet another embodiment, the processing chamber contains at least about 20% of fluorine-containing compound by volume. The remaining gas(es) may be one or more inert gases such as helium, neon, argon, krypton, xenon, and the like.

In one embodiment, the oxide layer 216 may be contacted with a plasma source gas in the processing chamber under suitable conditions to remove the oxide layer 216. The plasma source gas may include the fluorine-containing compound and optional one or more inert gases such as helium, neon, argon, krypton, xenon, and the like. The conditions generally depend upon, for example, the thiclkess of the oxide layer 216, the desired implementations and/or the semiconductor device being fabricated. In one embodiment, the plasma source gas may contain about 10% or more and about 50% or more of HF by volume. In another embodiment, the oxide layer 216 may be contacted with the plasma source gas by introducing a mixture of a fluorine-containing compound and inert gas into the processing chamber at a total gas flow of about 200 sccm or more and about 5000 sccm or more, at a temperature of about 10 degrees Celsius or more and about 100 degrees Celsius or less, at a pressure of about 10 Torr or less, with a source power of about 700 Watts and bias power of about 50 Watts. In yet another embodiment, the oxide layer 216 may be contacted with the plasma source gas by introducing a mixture of about 40 sccm a fluorine-containing compound such as SF₆ and about 60 sccm inert gas such as Ar into the processing chamber, at a temperature of about 10 degrees Celsius or more and about 100 degrees Celsius or less, at a pressure of about 8 Torr or less, with a source power of about 700 Watts and bias power of about 50 Watts.

FIG. 6 illustrates the structure after the oxide layer 216 is removed. There is substantially no oxide on the upper surface of the poly 1 214. Use of a SIMS analysis indicates that the oxygen count is at about the background noise level or less.

FIG. 7 illustrates formation of a poly 2 218 on one or more portions of the substrate 200 in the processing chamber after the oxide layer 216 is removed, thereby forming a zero angstrom oxide interface dual poly gate structure 220 for a semiconductor device 222. The poly 2 218 contains polysilicon. It is to be appreciated that the poly 2 218 can be formed employing substantially any suitable polysilicon formation techniques including CVD, with an optional patterned mask, followed by an optional etching away and/or etching back one or more portions.

The poly 2 218 is formed in the processing chamber at a suitable pressure to facilitate forming the poly layer that depends upon, for example, the thickness of the poly layer, the desired implementations and/or the semiconductor device being fabricated. The poly 2 218 may be formed in the processing chamber at a low pressure to mitigate re-formation of an oxide and/or oxide layer on the surface of the poly 1 214. In one embodiment, the poly 2 218 is formed at a pressure of about 500 Torr or less. In another embodiment, the poly 2 218 is formed at a pressure of about 200 Torr or less. In yet another embodiment, the poly 2 218 is formed at a pressure of about 100 Torr or less.

The poly 2 218 has a suitable thickness that depends upon the desired implementations and/or the semiconductor device being fabricated. In one embodiment, the thickness of poly 2 218 is about 0.01 micron or more and about 1 micron or less. In another embodiment, the thickness of poly 2 218 is about 0.02 microns or more and about 0.5 microns or less. In yet another embodiment, the thickness of poly 2 218 is about 0.05 microns or more and about 0.1 micron or less.

The poly 2 218 may have a thickness greater than, about equal to, or less than the thickness of poly 1 214. In one embodiment, the thickness of poly 2 218 is at least about 10% greater than the thickness of poly 1 214. In another embodiment, the thickness of poly 2 218 is at least about 25% greater than the thickness of poly 1 214. In yet another embodiment, the thickness of poly 2 218 is at least about 50% greater than the thickness of poly 1 214.

The formation of poly 2 218 may occur relatively soon or immediately after removing the oxide layer 216 to mitigate reformation of an oxide and/or oxide layer on the surface of the poly 1 214 prior to the formation of poly 2 218. In one embodiment, the formation of poly 2 218 starts within about 10 minutes after removing the oxide layer 216. In another embodiment, the formation of poly 2 218 starts within about 1 minute after removing the oxide layer 216. In yet another embodiment, the formation of poly 2 218 starts within about 10 seconds after removing the oxide layer 216.

The poly layers 214, 218 can be formed employing substantially any suitable poly formation techniques including CVD, with an optional patterned mask, followed by an optional etching away and/or etching back one or more portions. For example, an atmospheric pressure CVD (APCVD), low-pressure CVD (LPCVD), plasma-enhanced CVD (PECVD), or high-density plasma (HDP) may be employed. The CVD may introduce a gaseous form of a silicon-containing precursor, such as SiH₄, Si₂H₆, Si₃H₈, SiF₄, and the like above the substrate, with an inert gas such as helium and argon optionally being utilized as a carrier gas, through a gas delivery component.

The poly layer formation and oxide removal independently may be performed under an environment other than an oxygen-containing atmosphere such as air over the entire period or any portion of the period. The inert or non-reactive environment may be suitable for facilitating processing the zero angstrom oxide interface dual poly gate structure. For example, the chamber may contain an inert gas such as one or more of helium, neon, argon, krypton, xenon, and the like. The poly 1 214 is not exposed to the oxygen-containing atmosphere after removing oxide on the poly 1 214 and before the poly 2 218 is formed, thus not causing impurities at the interface between the poly 1 214 and poly 2 218, and improving, quality, and reliability of the semiconductor devices.

In one embodiment, any portion of or the entire of the poly layer formation and oxide removal independently may be performed under an inert atmosphere and less than about 0.001% oxygen by volume. In another embodiment, any portion of or the entire of the poly layer formation and oxide removal independently may be performed under an inert atmosphere and less than about 0.0005% oxygen by volume. In yet another embodiment, any portion of or the entire of the poly layer formation and oxide removal independently may be performed under an inert atmosphere and less than about 0.0001% oxygen by volume.

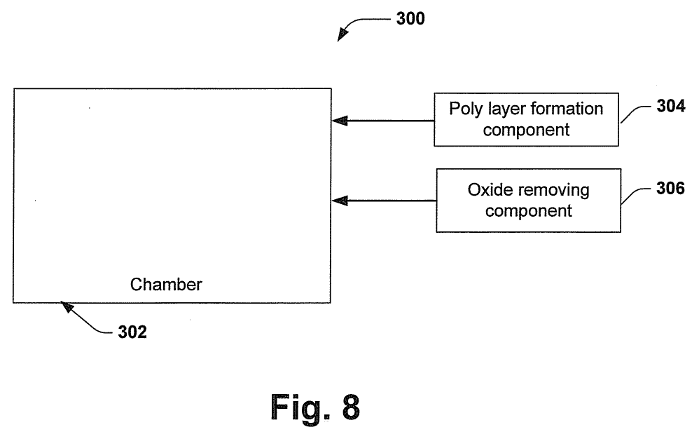

FIG. 8 illustrates a schematic block diagram of a system 300 for processing a zero angstrom oxide interface dual poly gate structure for a semiconductor device. The system 300 facilitates fabricating a zero angstrom oxide interface dual poly gate structure containing at least two poly layers. The zero angstrom oxide interface dual poly gate structure has substantially no oxide interface layer between the poly layers. The system 300 includes a processing chamber 302 defined by a housing having a plurality of walls. The system 300 includes one or more poly layer formation components 304 associated with the chamber 302 operative to form a poly layer on one or more portions of a substrate in the chamber 302, and one or more oxide removing components 306 associated with the chamber 302 operative to contact the poly layer with at least one of hydrogen, nitrogen, and fluorine-containing compound to remove an oxide on the poly layer in the chamber 302.

It is to be appreciated that substantially any suitable type of process chamber 302 can be used for the subject invention. For example, the chamber 302 may be a CVD chamber, a PVD chamber, or other commonly available semiconductor processing chamber, with or without appropriate modifications. The processing chamber 302 can be substantially any enclosure associated with one or more gas and/or liquid inlets to deliver gaseous and/or liquid chemicals for forming the poly layer and for removing an oxide from the surface of the poly layer, and at least one gas and/or liquid outlet for evacuating the enclosure. The processing chamber 302 may be a single- or multiple-wafer chamber. The processing chamber 302 may have subchambers.

One or more poly layer formation components 304 can be employed associated with the processing chamber 302. The poly layer formation component 304 may include a monitoring and controlling component that facilitates, among other things, depositing the poly layer to a desired thickness on one or more portions of the substrate. The poly layer formation components 304 may be, for example, a CVD component. It is to be appreciated that substantially any suitable poly layer formation components 304 may be employed with the subject invention. For example, components that use PVD techniques, oxidation techniques, or gas phase reactions may be employed in accordance with the subject invention. Choice of a suitable poly layer formation component 304 depends primarily on the identity of the precursor material of the poly layer, size of substrates being processed, and to some extent, the composition of a substrate and/or an insulator layer. It is to be appreciated that each of the various poly layer formation components 304 has its own set of features and characteristics in the art.

A poly layer formation CVD component 304 generally includes a CVD reactor and a gas delivery system having conduits for delivery of gases to the chamber 302. Substantially any suitable poly layer formation components 304 using CVD techniques may be employed with the subject invention. For example, an atmospheric pressure CVD (APCVD), low-pressure CVD (LPCVD), plasma-enhanced CVD (PECVD), or high-density plasma (HDP) may be employed.

In one embodiment, a poly layer formation component 304 may be a PECVD. The PECVD typically comprises a plasma-generating component and a gas delivery component. The PECVD may introduce a gaseous form of a silicon-containing precursor, such as SiH₄, Si₂H₆, Si₃H₈, SiF₄, and the like above the substrate, with an inert gas such as helium and argon optionally being utilized as a carrier gas, through the gas delivery component.

One or more oxide removing components 306 can be employed associated with the processing chamber 302 to contact the poly layer with at least one of hydrogen, nitrogen, fluorine-containing compound, and other oxide removing ambients to remove an oxide and/or oxide layer on the poly layer. An oxide removing component 306 generally includes a gas-supplying component and a gas delivery component having conduits for supply and delivery of at least one of hydrogen, nitrogen, fluorine-containing compound, and other oxide removing ambients to the chamber 302. The oxide removing component 306 may include a monitoring and controlling component that facilitates, among other things, removing the oxide on the poly layer. It is to be appreciated that substantially any suitable oxide removing components 306 may be employed with the subject invention. The oxide removing component 306 may include, for example, a hydrogen cylinder, nitrogen cylinder, and/or fluorine-containing compound cylinder. The oxide removing component 306 introduces at least one of hydrogen, nitrogen, and fluorine-containing compound into the processing chamber 302 to contact the poly layer with at least one of the hydrogen, nitrogen, and fluorine-containing compound under suitable conditions to remove an oxide on the poly layer.

The oxide removing components 306 contact the poly layer with at least one of hydrogen, nitrogen, and fluorine-containing compound in the processing chamber 302 at suitable conditions to facilitate removing the oxide on the poly layer. The conditions generally depend upon, for example, the thickness of the oxide layer, the desired implementations and/or the semiconductor device being fabricated. In one embodiment, the poly layer is contacted with at least one of hydrogen, nitrogen, and fluorine-containing compound at a temperature of about 200 degrees Celsius or more and about 950 degrees Celsius or less, at a pressure of about 10 Torr or less, and for about 1 second or more and about 30 minutes or less.

A poly layer formation component 304 and oxide removing component 306 independently may perform the dual poly gate structure formation processes under environment other than an oxygen-containing atmosphere such as air in the processing chamber 302. The inert or non-reactive environment may be suitable for facilitating processing the zero angstrom oxide interface dual poly gate structure. For example, the chamber 302 may contain an inert gas such as one or more of helium, neon, argon, krypton, xenon, and the like. As a result, the poly layer is not exposed to the oxygen-containing atmosphere after formation of the poly 1 and before the formation of the poly 2, thus not causing impurities at the interface between the poly 1 and poly 2, and improving, quality, and reliability of the semiconductor devices. Even if the chamber 302 has subchambers, the layers are not exposed to air because the substrate is not transferred from a subchamber to another subchamber with an air break. The enclosing chamber 302 with subchambers excludes the air.

In one embodiment, the chamber 302 contains an inert atmosphere and less than about 0.001% oxygen by volume. In another embodiment, the chamber 302 contains an inert atmosphere and less than about 0.0005% oxygen by volume. In yet another embodiment, the chamber 302 contains an inert atmosphere and less than about 0.0001% oxygen by volume.

A poly layer formation component 304 and an oxide removing component 306 may independently perform the optional heat treatment/annealing under an inert or non-reactive environment other than an oxygen-containing environment. For example, the chamber 302 in which heating takers place may contain an inert gas such as one or more of helium, neon, argon, krypton, xenon, and a mixture thereof.

A poly layer formation component 304 generally includes a delivery component which is operatively coupled to the chamber 302 for selectively providing gaseous and/or liquid chemicals into the chamber 302 at various rates, volumes, concentrations, etc. based upon, among other things, the amount (thickness) of layer(s) to be formed, the composition of layer(s) to be formed, the pressure within the chamber 302, the temperature within the chamber 302 and/or the size of the chamber 302, for example. An oxide removing component 306 generally includes a delivery component which is operatively coupled to the chamber 302 for selectively providing gaseous and/or liquid chemicals into the chamber 302 at various rates, volumes, concentrations, etc. based upon, among other things, the amount (thiclkess) of layer(s) to be removed, the composition of layer(s) to be removed, the pressure within the chamber 302, the temperature within the chamber 302 and/or the size of the chamber 302, for example.

By way of illustration, the gas delivery components include one or more sources of gaseous medium (a vapor) of one or more chemical(s). In one example, the gases may be provided into the chamber 302 through a conduit that terminates in a nozzle (not shown). It is to be appreciated that more than one nozzle or other gas delivery mechanisms may be utilized to provide gas into the chamber 302 at various mixtures and/or concentrations in accordance with one or more aspects of the subject invention. For example, a shower head type gas delivery mechanism can be implemented to more evenly provide chemicals into the chamber 302 above the substrate, which can facilitate a more uniform chemical vapor deposition and/or a more uniform oxide removal on and across the substrate. An inert or non-reactive gaseous can also be provided into the chamber 302 to avoid oxygen exposure of the poly layer after the removal of the oxide on the surface of the poly layer.

Although not shown, the system 300 may contain substantially any component for processing all or portions of the semiconductor devices. For example, the system 300 may contain substantially any components for masking, patterning, etching, planarization, thermal oxidation, implant, annealing, thermal treatment, deposition, and the like normally used for semiconductor devices.

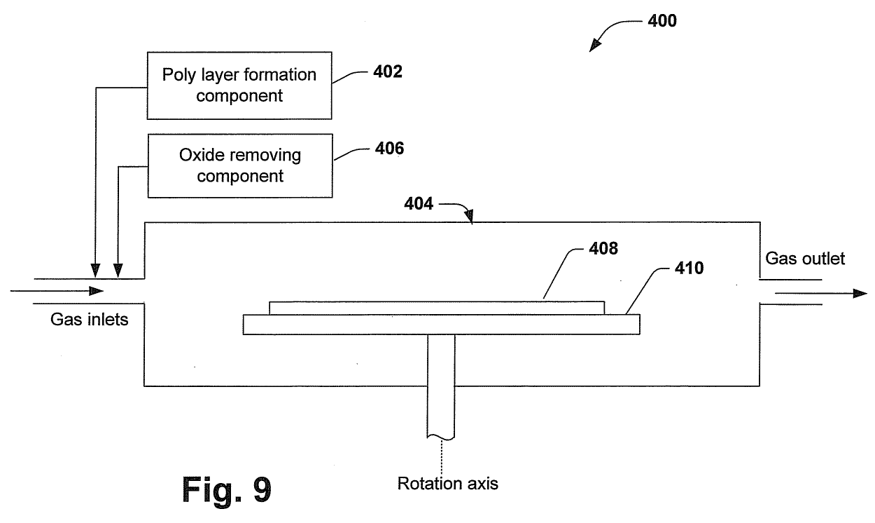

FIG. 9 shows a schematic block diagram illustrating a system 400 for processing a zero angstrom oxide interface dual poly gate structure for a semiconductor device. The system facilitates fabricating a zero angstrom oxide interface dual poly gate structure containing at least two poly layers. The zero angstrom oxide interface dual poly gate structure has substantially no oxide interface layer between the poly layers. The system 400 includes one or more poly layer formation components 402 associated with a chamber 404 operative to form a poly layer on one or more portions of a substrate, and one or more oxide removing components 406 associated with the chamber 404 operative to contact the poly layer with at least one of hydrogen, nitrogen, fluorine-containing compound, and other oxide removing ambients to remove an oxide and/or oxide layer on the surface of the poly layer.

The processing chamber 404 is configured for receiving and processing a substrate 408 in a predefined manner. The chamber 404 may have a cylindrical sidewall that may enclose a rotatable chuck 410 onto which the substrate 408 is mounted for processing. The chuck 410 may include a vacuum system (not shown) for holding the substrate 408 on its surface during processing. The chamber 404 has gas inlets for conveying gases to the chamber 404 and a gas outlet for removing gases from the chamber 404. The inlets are connected to the poly layer formation component 402 and the oxide removing component 406.

In one embodiment, the poly layer formation component 402 may be a PECVD. The PECVD typically comprises a plasma-generating component and a gas delivery component. The PECVD may introduce a gaseous form of a silicon-containing precursor, such as SiH₄, Si₂H₆, Si₃H₈, SiF₄, and the like above the substrate, with an inert gas such as helium and argon optionally being utilized as a carrier gas, through the gas delivery component.

In one embodiment, the oxide removing component 406 may include a gas-supplying component and a gas delivery component having conduits for supply and delivery of at least one of hydrogen, nitrogen, fluorine-containing compound, and other oxide removing ambients to the chamber 404. The oxide removing component 406 provides the chamber 404 with at least one of hydrogen, nitrogen, fluorine-containing compound, and other oxide removing ambients through the gas delivery component and gas inlet to remove an oxide and/or oxide layer that is present on the surface of the poly layer. In one embodiment, the poly layer is contacted with at least one of hydrogen, nitrogen, and fluorine-containing compound at a temperature from about 400 degrees Celsius to about 850 degrees Celsius, at a pressure of about 6 Torr or less, and for a time from about 10 seconds to about 5 minutes.

Although not shown, the system 400 may contain substantially any components for processing all or portions of the semiconductor devices. For example, the system may contain substantially any components for masking, patterning, etching, planarization, thermal oxidation, implant, annealing, thermal treatment, deposition, and the like normally used for semiconductor devices.

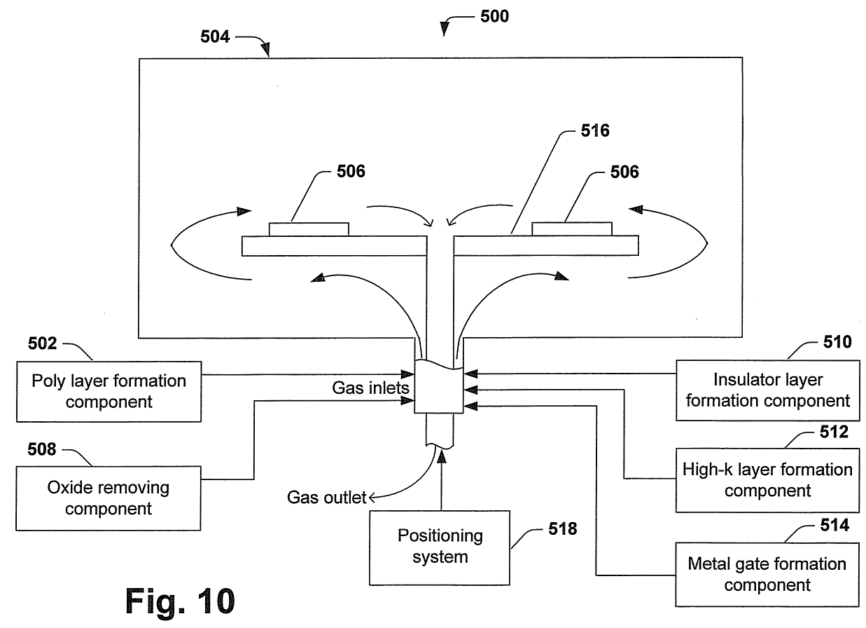

FIG. 10 shows a schematic block diagram illustrating a system 500 for processing a zero angstrom oxide interface dual poly gate structure for a semiconductor device. The system facilitates fabricating a zero angstrom oxide interface dual poly gate structure containing at least two poly layers. The zero angstrom oxide interface dual poly gate structure has substantially no oxide interface layer between the poly layers.

The system 500 includes one or more poly layer formation components 502 associated with a chamber 504 operative to form a poly layer on one or more portions of a substrate 506 and one or more oxide removing components 508 associated with the chamber 504 operative to contact the poly layer with at least one of hydrogen, nitrogen, and fluorine-containing compound to remove an oxide and/or oxide layer from the surface of the poly layer. The system may optionally include 1) one or more insulator layer formation components 510 associated with the chamber 504 operative to form an insulator layer on one or more potions of the substrate 506, 2) one or more high-k layer formation components 512 associated with the chamber 504 operative to form a high-k layer on one or more potions of the substrate 506, and 3) one or more metal gate layer formation components 514 associated with the chamber 504 operative to form a metal gate layer on one or more potions of the substrate 506.

The processing chamber 504 is configured for receiving and processing multiple wafer substrates 506 in a predefined manner. The chamber 504 may have a cylindrical sidewall that may enclose a rotatable chuck 516 onto which multiple substrates 506 are mounted for processing. A positioning system 518 may be operatively connected to the rotatable chuck 516 for selectively maneuvering the substrates 506 into desired positions within the chamber 504. The chuck 516 typically includes a vacuum system (not shown) for holding the substrates on its surface during processing. The chamber 504 has gas inlets for conveying gases to the chamber 504 and a gas outlet for removing gases from the chamber 504. The poly layer formation component 502, the oxide removing component 508, the insulator layer formation component 510, the high-k layer formation component 512, and the metal gate layer formation component 514 are connected to the gas inlets of the chamber 504.

Although not shown, the system 500 may contain substantially any components for processing all or portions of semiconductor devices. For example, the system may contain substantially any components for masking, patterning, etching, planarization, thermal oxidation, implant, annealing, thermal treatment, deposition, and the like normally used for semiconductor devices.

The semiconductor devices containing the zero angstrom oxide interface dual poly gate structure in accordance with the subject invention are useful in substantially any electric components. For example, the semiconductor devices are useful in computers, appliances, industrial equipment, hand-held devices, telecommunications equipment, medical equipment, research and development equipment, transportation vehicles, radar/satellite devices, and the like. Examples of hand-held devices include cell phones and other two way communication devices, personal data assistants, palm pilots, pagers, notebook computers, remote controls, recorders (video and audio), radios, small televisions and web viewers, cameras, and the like.

With respect to any figure or numerical range for a given characteristic, a figure or a parameter from one range may be combined with another figure or a parameter from a different range for the same characteristic to generate a numerical range.

While the invention has been explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

In particular regard to the various functions performed by the above described components (assemblies, devices, circuits, etc.), the terms (including substantially any reference to a “means”) used to describe such components are intended to correspond, unless otherwise indicated, to substantially any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for substantially any given or particular application.

1. A method for forming a zero angstrom oxide interface between two poly layers for a dual poly gate structure for a semiconductor device, consisting essentially of:
contacting a substrate comprising a first poly layer with a material selected from the group consisting essentially of hydrogen, nitrogen, fluorine-containing compound, and combinations thereof to remove an oxide and/or oxide layer on the first poly layer in a processing chamber; and
forming a second poly layer on the first poly layer in the processing chamber,
wherein an interface of the first poly layer and the second poly layer comprises substantially no oxide.

2. The method of claim 1 wherein the first poly layer is contacted with at least one of hydrogen, nitrogen, and fluorine-containing compound at a temperature of about 200 degrees Celsius or more and about 950 degrees Celsius or less, at a pressure of about 10 Torr or less, and for about 1 second or more and about 30 minutes or less.

3. The method of claim 1 wherein the fluorine-containing compound is selected from a group consisting of F₂, HF, NF₃, SF₆, SF₄, S₂F₂, S₂F₁₀, S₃H₈, CF₃, CF₄, CH₂F₂, CHF₃, CH₃F, C₂H₂F₂, C₂H₄F₆, C₂F₆, C₃F₈, C₄F₈, C₂HF₅, C₄F₁₀, CF₂Cl₂, CFCl₃, C₂F₄C₁₂, SiF₄, Si₂F₆, SiHF₃, SiH₂F₂, SiH₃F, SiCl₂F₂, and SiClF₃.

4. The method of claim 1 wherein the second poly layer is formed at a pressure of about 500 Torr or less.

5. The method of claim 1 wherein forming the second poly layer starts within about 10 minutes after removing the oxide and/or oxide layer.

6. The method of claim 1 wherein the processing chamber comprises an inert atmosphere and less than about 0.001% oxygen by volume.

7. The method of claim 1 wherein the processing chamber comprises an enclosure of a small volume such that the processing chamber processes about 10 or fewer substrates.

8-10. (canceled)

11. A system for forming a zero angstrom oxide interface between two poly layers for a dual poly gate structure for a semiconductor device, consisting essentially of:
a processing chamber;
a poly layer formation component associated with the chamber operative to form a poly layer on one or more portions of a substrate; and
an oxide removing component associated with the chamber operative to contact the poly layer with at-least-one a material selected from the group consisting essentially of hydrogen, nitrogen, and fluorine-containing compound, and combinations thereof to remove an oxide and/or oxide layer on the poly layer.

12. The system of claim 11 wherein the oxide removing component is capable of operation to contact the poly layer with at least one of hydrogen, nitrogen, and fluorine-containing compound at a temperature of about 200 degrees Celsius or more and about 950 degrees Celsius or less, at a pressure of about 10 Torr or less, and for about 1 second or more and about 30 minutes or less.

13. The system of claim 11 wherein the oxide removing component is capable of operation to contact the poly layer with at least one of hydrogen, nitrogen, and fluorine-containing compound at a temperature of about 400 degrees Celsius or more and about 850 degrees Celsius or less, at a pressure of about 6 Torr or less, and for about 10 seconds or more and about 5 minutes or less.

14. The system of claim 11 wherein the processing chamber comprises an enclosure of a small volume such that the processing chamber processes about 10 or fewer substrates.

15. The system of claim 11 wherein the poly layer formation component is capable of operation to form a second poly layer on a first poly layer at a pressure of about 500 Torr or less.

16. The system of claim 11 wherein the poly layer formation component is capable of operation to start forming a second poly layer on a first poly layer within about 10 minutes after the oxide removing component removes the oxide and/or oxide layer on the first poly layer.

17-20. (canceled)

21. The method of claim 1, wherein the substrate is contacted with the material by delivering gas consisting essentially of hydrogen, nitrogen, fluorine-containing compound, and combinations thereof into the processing chamber.

22. The method of claim 1, wherein the substrate is contacted with a plasma source gas consisting essentially of the fluorine-containing compound in the processing chamber.

23. The method of claim 1, wherein the substrate is contacted with the material by introducing a mixture of a fluorine-containing compound and inert gas.

24. A method for forming a dual poly gate structure, comprising:
forming a zero angstrom oxide interface between two poly layers, consisting essentially of: contacting a substrate comprising a first poly layer with a material selected from the group consisting essentially of hydrogen, nitrogen, fluorine-containing compound, and combinations thereof to remove an oxide and/or oxide layer on the first poly layer in a processing chamber; and forming a second poly layer on the first poly layer in the processing chamber, wherein an interface of the first poly layer and the second poly layer comprises substantially no oxide, and
forming at least one of an insulator layer, a high-k layer, or a metal gate layer on one or more portions of the substrate in the chamber.

25. The method of claim 24, wherein the substrate is contacted with the material by delivering gas consisting essentially of hydrogen, nitrogen, fluorine-containing compound, and combinations thereof into the processing chamber.

26. The method of claim 24, wherein the substrate is contacted with a plasma source gas consisting essentially of the fluorine-containing compound in the processing chamber.

27. The method of claim 24, wherein the substrate is contacted with the material by introducing a mixture of a fluorine-containing compound and inert gas.
